(19) United States
(12) Patent Application Publication
(10) Pub. No.: US 2015/0295124 A1
(43) Pub. Date: Oct. 15, 2015

(54) MANUFACTURING EQUIPMENT FOR PHOTOVOLTAIC DEVICES AND METHODS

(71) Applicants: Koji Matsumaru, Nagaoka-shi (JP); Jose Briceno, Tokyo-to (JP)

(72) Inventors: Koji Matsumaru, Nagaoka-shi (JP); Jose Briceno, Tokyo-to (JP)

(21) Appl. No.: 14/216,474

(22) Filed: Mar. 17, 2014

Related U.S. Application Data
(63) Continuation-in-part of application No. 13/844,298, filed on Mar. 15, 2013, now Pat. No. 8,952,246.
Application No. 13/844,298 is a continuation-in-part of application No. 13/844,428, filed on Mar. 15, 2013.
Application No. 13/844,428 is a continuation-in-part of application No. 13/844,521, filed on Mar. 15, 2013, now Pat. No. 9,099,578.
Application No. 13/844,521 is a continuation-in-part of application No. 13/844,747, filed on Mar. 15, 2013.
Application No. 13/844,747 is a continuation-in-part of application No. 13/844,686, filed on Mar. 15, 2013.
(60) Provisional application No. 61/801,019, filed on Mar. 15, 2013.
(60) Provisional application No. 61/800,800, filed on Mar. 15, 2013.
(60) Provisional application No. 61/800,912, filed on Mar. 15, 2013.
(60) Provisional application No. 61/801,145, filed on Mar. 15, 2013.
(60) Provisional application No. 61/801,244, filed on Mar. 15, 2013.
(60) Provisional application No. 61/619,410, filed on Apr. 2, 2012.
(60) Provisional application No. 61/722,693, filed on Nov. 5, 2012.
(60) Provisional application No. 61/655,449, filed on Jun. 4, 2012.
(60) Provisional application No. 61/738,375, filed on Dec. 17, 2012.
(60) Provisional application No. 61/761,342, filed on Feb. 6, 2013.
(60) Provisional application No. 61/715,283, filed on Oct. 17, 2012.
(60) Provisional application No. 61/715,286, filed on Oct. 18, 2012.
(60) Provisional application No. 61/715,287, filed on Oct. 18, 2012.

(51) Int. Cl. H01L 31/18

(52) U.S. Cl. CPC H01L 31/1876; H01L 31/1864

(57) ABSTRACT

A multi-chamber PV furnace and method for continuously processing the wafers is described. A preferred embodiment includes three main chambers that allow pre-heating, heating, and cooling of the target material in a streamlined process designed for continuous operation in a mass production environment. The three-chamber design shortens the processing time and permits continuous processing of batches of substrate material in an in-line fashion. Each of the three chambers or zones allows for independent control and management of processing temperature, pressure, and atmosphere by means of inlet gate and outlet gate valve mechanisms.

### CROSS-REFERENCE TO RELATED APPLICATIONS

This application claims the benefit of U.S. application Ser. No. 13/844,686, filed Mar. 15, 2013 (Attorney Docket No. 44671-047 (P7)); U.S. Provisional Application No. 61/761,342, filed Feb. 6, 2013 (Attorney Docket No. 44671-047 (P7)); U.S. application Ser. No. 13/844,298, filed Mar. 15, 2013 (Attorney Docket No. 44671-033 (P2)); U.S. Provisional Application No. 61/619,410, filed Apr. 2, 2012 (Attorney Docket No. 44671-033 (P2)); U.S. application Ser. No. 13/844,428, filed Mar. 15, 2013 (Attorney Docket No. 44671-034 (P3)); U.S. Provisional Application No. 61/722,693, filed Nov. 5, 2012 (Attorney Docket No. 44671-034 (P3)); U.S. application Ser. No. 13/844,521, filed Mar. 15, 2013 (Attorney Docket No. 44671-035 (P4)); U.S. Provisional Application No. 61/655,449, filed Jun. 4, 2012 (Attorney Docket No. 44671-035 (P4)); U.S. application Ser. No. 13/844,747, filed Mar. 15, 2013 (Attorney Docket No. 44671-038 (P5)); U.S. Provisional Application No. 61/738,375, filed Dec. 17, 2012 (Attorney Docket No. 44671-038 (P5)); U.S. Provisional Application No. 61/715,283, filed Oct. 17, 2012 (Attorney Docket No. 44671-041 (P12)); U.S. Provisional Application No. 61/715,286, filed Oct. 18, 2012 (Attorney Docket No. 44671-043 (P13)); U.S. Provisional Application No. 61/715,287, filed Oct. 18, 2012 (Attorney Docket No. 44671-044 (P14)); U.S. Provisional Application No. 61/801,019, entitled Manufacturing Equipment for Photovoltaic Devices, filed 15 Mar. 2013 (Attorney Docket No. 44671-050 (P 32)); U.S. Provisional Application No. 61/800,912, entitled Infrared Photovoltaic Device, filed 15 Mar. 2013 (Attorney Docket No. 44671-049 (P 10)); U.S. Provisional Application No. 61/800,800, entitled Hybrid Transparent Electrode Assembly for Photovoltaic Cell Manufacturing, filed 15 Mar. 2013 (Attorney Docket No. 44671-048 (P23)); U.S. Provisional Application No. 61/801,145, entitled PIN Photo-voltaic device and Manufacturing Method, filed 15 Mar. 2013 (Attorney Docket No. 44671-051 (P 17)), and U.S. Provisional Application No. 61/801,244, entitled Infrared Photo-voltaic device and Manufacturing Method, filed 15 Mar. 2013 (Attorney Docket No. 44671-052 (P36)), the entireties of which are incorporated by reference as if fully set forth herein.

This application is related to U.S. Provisional Application No. 61/722,693, filed 5 Nov. 2012 (docket number P 3) U.S. Provisional Application No. 61/715,283, filed 17 Oct. 2012 (docket number P 12); U.S. Provisional Application No. 61/715,286, filed 18 Oct. 2012 (docket number P 13); U.S. Provisional Application No. 61/715,287, filed 18 Oct. 2012 (docket number P 14); U.S. Provisional Application No. 61/761,342, filed 6 Feb. 2013 (docket number P7); copending U.S. non-Provisional Application No. 13/844,428, filed 15 Mar. 2013 (docket number P3, sub case 002); and copending U.S. non-Provisional Application No. 13/844,686, filed 15 Mar. 2013 (docket number P7, sub case 003); the entireties of which are incorporated by reference as if fully set forth here reference as if fully set forth herein.

### FIELD OF THE INVENTION

The present invention relates to equipment for the fabrication of photovoltaic devices or cells, and in particular, a multi-chamber furnace designed to manufacture such devices.

### BACKGROUND OF THE INVENTION

Prior apparatus used in the manufacture of photovoltaic materials typically employ a single chamber furnace. For example, Aoki, U.S. Pat. No. 7,871,502, issued Jan. 18, 2011, describes a furnace for the selenization of thin film photovoltaic materials that has only one closed reaction chamber.

Hsiao et. al., U.S. Pat. No. 8,591,824, issued Nov. 26, 2013, provides a design for a single chamber heat treating furnace for producing copper-indium-gallium-selenide solar cells.

### BRIEF SUMMARY OF PREFERRED EMBODIMENTS OF THE INVENTION

The present invention provides manufacturing equipment for processing photovoltaic devices in which one or more photovoltaic (PV) structures, i.e., silicon wafers, glass or other substrates, are placed within a substrate or wafer boat for movement through a multi-chamber furnace, which has a number advantages over the prior single chamber furnaces.

One embodiment of the present invention is a multi-chamber PV furnace for continuously processing the wafers as the wafers within the boat move from one chamber to another. More specifically, the embodiment includes three main chambers that allow pre-heating, heating, and cooling of the target material in a streamlined process designed for continuous operation in a mass production environment. The three-chamber design shortens the processing time and permits continuous processing of batches of substrate material in an in-line fashion. The apparatus of the present invention increases productivity and minimizes the time for mass production of PV devices. Each of the three chambers or zones allows for independent control and management of processing temperature, pressure, atmosphere, by means of inlet gate and outlet gate valve mechanisms.

In a preferred embodiment of the present invention, a multi-chamber thermo photovoltaic furnace includes the following: a first chamber, also referred to as a first heating chamber or staging chamber, for preheating a plurality of substrates positioned within one or more substrate boats to a desired condition; a second chamber, also referred to as a second heating chamber or main heating chamber, for heating the substrates to a desired temperature under controlled process conditions; and a third chamber, also referred to as a third heating chamber, post-processing chamber or cooling chamber, for cooling down the substrates.

An inlet gate valve is operably connected to an inlet gate of the first chamber for loading the chamber with the substrate boats containing the wafers. This inlet gate valve allows for the loading of the first chamber while maintaining all of the chambers at the controlled conditions of temperature, pressure, or vacuum and to prevent loss of processing gases.

An intermediate gate valve is operably connected between an outlet gate of the first chamber and an inlet gate of the second chamber for allowing the substrate boats to move from the first chamber into the second chamber. The intermediate gate valve not only allows the wafer boats to move continuously from one chamber to another, but it also maintains the same pressure and process gas atmosphere in both chambers.

A third chamber is operably connected to the outlet gate of said second chamber for cooling down the substrates.

An outlet gate valve is operably connected to an outlet gate of the third chamber for unloading the substrate boat while maintaining the controlled process conditions within said first and second chambers.

### BRIEF DESCRIPTION OF THE DRAWINGS

Preferred embodiments of the present invention are illustrated by way of example, and not by way of limitation, in the figures of the accompanying drawings and in which like reference numerals refer to similar elements and in which:

FIG. 1 is a diagrammatic view of a cross-section of a typical PV device 1 being processed in the apparatus of an embodiment of the present invention.

FIG. 2 is a diagrammatic cross-section view illustrating the multi-chamber heating apparatus 100 of the present invention.

FIG. 3 is a simplified cross-section diagrammatic view illustrating the three stages of one embodiment of the multi-chamber heating apparatus 200 of the present invention showing the direction the PV devices travel through each of the chambers.

FIG. 4 is a diagrammatic cross-section view illustrating the heating chamber 300 of one embodiment of the present invention.

FIG. 5 is a diagrammatic cross-section view illustrating multi-chamber heating apparatus 400 in standby stage or mode to receive the PV devices in one embodiment of the present invention.

FIG. 6 is a diagrammatic cross-section view illustrating the multi-chamber heating apparatus 500 in its substrate loading stage as it receives an initial wafer boat containing the PV devices in one embodiment of the present invention.

FIG. 7 is a diagrammatic cross-section view illustrating the multi-chamber heating apparatus 600 in its substrate loading and processing stage for treating the PV devices in one embodiment of the present invention.

FIG. 8 is diagrammatic cross-section view illustrating the multi-chamber heating apparatus 700 loading and unloading stages in one embodiment of the present invention.

### DETAILED DESCRIPTION OF PREFERRED EMBODIMENTS OF THE INVENTION

In the following description numerous specific details have been set forth to provide a more thorough understanding of embodiments of the present invention. It will be appreciated however, by one skilled in the art, that embodiments of the invention may be practiced without such specific details or with different implementations for such details. Additionally some well-known structures have not been shown in detail to avoid unnecessarily obscuring the present invention.

Subject material (or substrate) boat: The substrate boat is the mechanism that allows placement of the substrate inside the multi-chamber heating apparatus, and also allows to move from one chamber to the next. The multi-chamber heating furnace is capable of processing the substrate in a continuous operation mode, in “in-line” setup, for mass production. Depending on the dimensions of the chambers described below, this furnace assembly is able to process a large number of substrates. As an example, the substrate boat (or wafer boat) may hold about 200 wafers, which individual size may be 156×156 mm. The size of the wafer boat will determine the furnace assembly dimensions, as well as the dimensions of each chamber, and therefore the location and properties (or specifications) of the remaining components of the furnace, such as heating elements, vacuum exhaust valves, gas inlet valves, and other similar equipment, will make the furnace function properly.

Each heating chamber is preferably equipped with an independent heating mechanism. The pressure, or level of vacuum, can be independently controlled for each chamber. Similarly, an internal atmosphere or processing gas in each chamber may be independently controlled for each chamber.

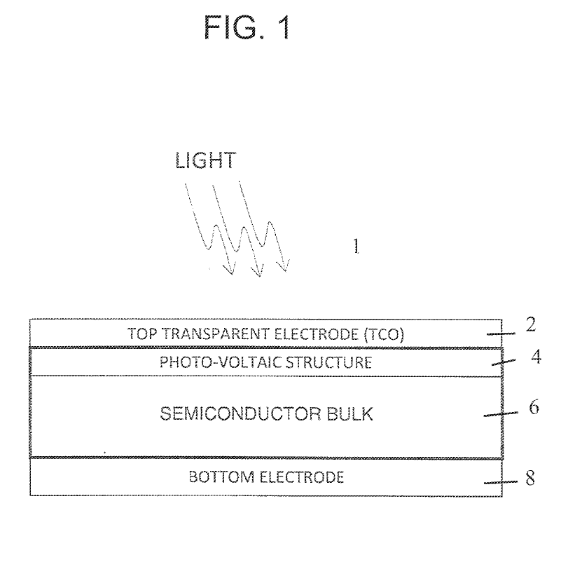

FIG. 1 is a representation of a typical PV device 1 which includes a top coating of a transparent electrode 2 deposited on a PV structure 4 formed on a semiconductor bulk 6 and to which a bottom electrode 8 is deposited. The inclusion of such a device in this description of the preferred embodiment is to illustrate one of the numerous types of substrates that are more effectively treated in the furnace of the present invention man in the prior art furnaces.

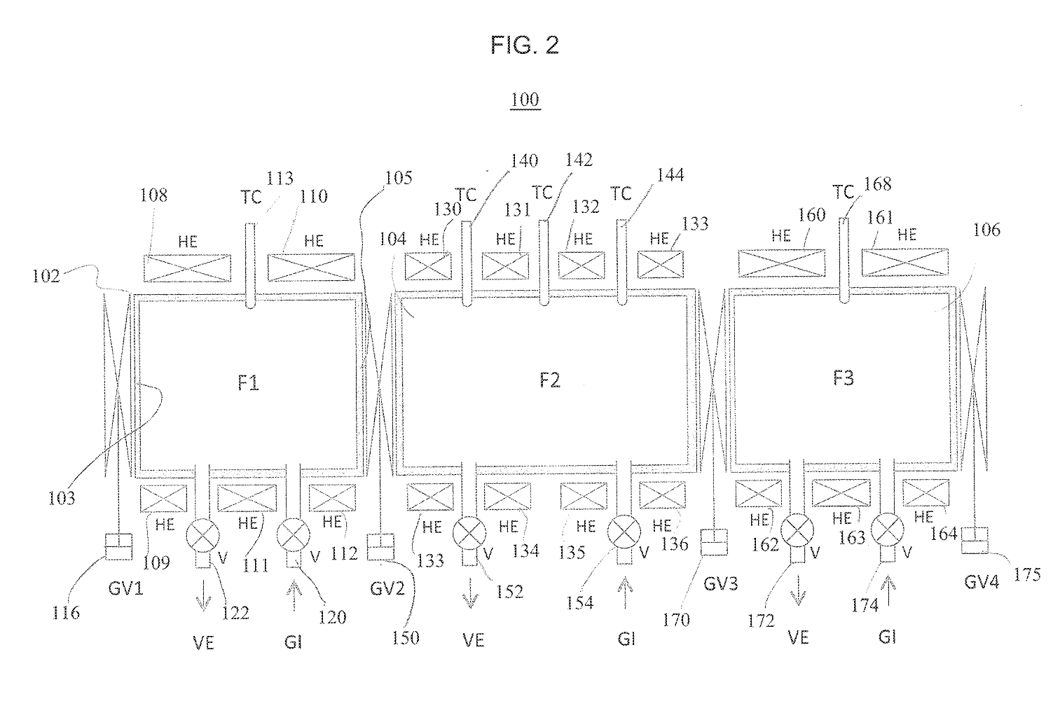

Referring to FIG. 2, inlet gate valve mechanism (GV1) 116 is shown operably connected to inlet gate 103 of chamber 102 of multi-chamber heating apparatus 100. The inlet gate valve 116 mechanism of chamber 102 allows the loading of the chamber with the substrate to be processed, while keeping the other two chambers under controlled conditions. Thermocouple (TC) 113 assists in maintaining control of the temperature in chamber 102. The pressure is controlled by the process gas that enters chamber 103 via gate inlet (GI) valve 120. The vacuum is controlled by vacuum exhaust (VE) 122. Chamber 102 (F1), which is the first heating chamber or staging chamber and is mainly used to pre-heat the substrate (silicon wafers, glass substrate, and other materials to be processed) to the target conditions under the desired pressure and process gas.

Intermediate gate valve mechanism 150 (GV2) in FIG. 2 is shown operably connected between outlet gate 105 of chamber 102 and inlet gate 107 of chamber 104: The gate valve mechanism 150 between chamber 102 and chamber 104 functions as a load lock mechanism. This allows mobilizing the subject material (or substrate) from chamber 102 to chamber 104, and maintaining the same pressure and process gas atmosphere in both chambers. As described above, vacuum is controlled by vacuum VE 152 and the process gas enters chamber 104 via GI valve 154. Heating elements (HE) 108, 109, 110, 111 and 112 are distributed around chamber 102 to assist in maintaining a constant temperature throughout chamber 102 and monitored by TC 140, TC 142, and TC 144.

The design of chamber 104 (F2 in FIG. 2), which is the second heating chamber or main heating chamber, is essentially similar to that of chamber 102. In addition, HE 130, 131, 132, 133, 134, 135, 136 and 137 of chamber 104 are vertically synchronized so the soaking zone may be maximized throughout the whole chamber. In addition to very close temperature management, chamber 104 also features independent internal atmosphere control i.e., process gas and/or vacuum.

Chamber 104 is used to process the substrate at the desired temperature and other atmospheric conditions. Chamber 104 is pre-heated to the desired processing temperature prior to introduce the substrate such as that shown in FIG. 1. Then the substrate is introduced into chamber 104 for the desired time and heated to the desired temperature, time, and under the desired pressure and process gas atmosphere. Once the heating process is completed, the substrate is mobilized to the next chamber 106 via the gate valve mechanism 170.

Intermediate gate valve mechanism (GV3 in FIG. 2) 170 is operably connected between chamber 104 and chamber 106 and functions as a load lock mechanism, that allows mobilizing the substrate (or substrate) from chamber 104 and chamber 106 while maintaining the same pressure, and process gas atmosphere in both chambers. Once the substrate is mobilized from chamber 104 and chamber 106, chamber 104 may be prepared to receive a new load of substrate.

The design of chamber 106 (F3 in FIG. 2) is similar to that of chamber 102 and chamber 104 having HE 160, 161, 162, 163 and 164 and is used to cool down the substrate so it can be handled and unloaded to the next processing step, i.e., the post-heat treatment stage of a typical manufacturing operation. Chamber 106 is able to closely control the substrate cooling rate to up to 200° K per minute as monitored by means of TC 168, vacuum by means of VE 172 and an inert gas flow through GI 174. In addition to fast cooling, this chamber also functions as an initial post processing step, when temperature profile, gas and pressure need to be independently manipulated for such a process.

Outlet gate valve mechanism 175 (GV4 in FIG. 2) of chamber 106 allows the substrate boat to be unloaded from chamber 106, while keeping the chambers 102 and chamber 104 under controlled conditions of unchanged temperature, pressure, process gas, or vacuum.

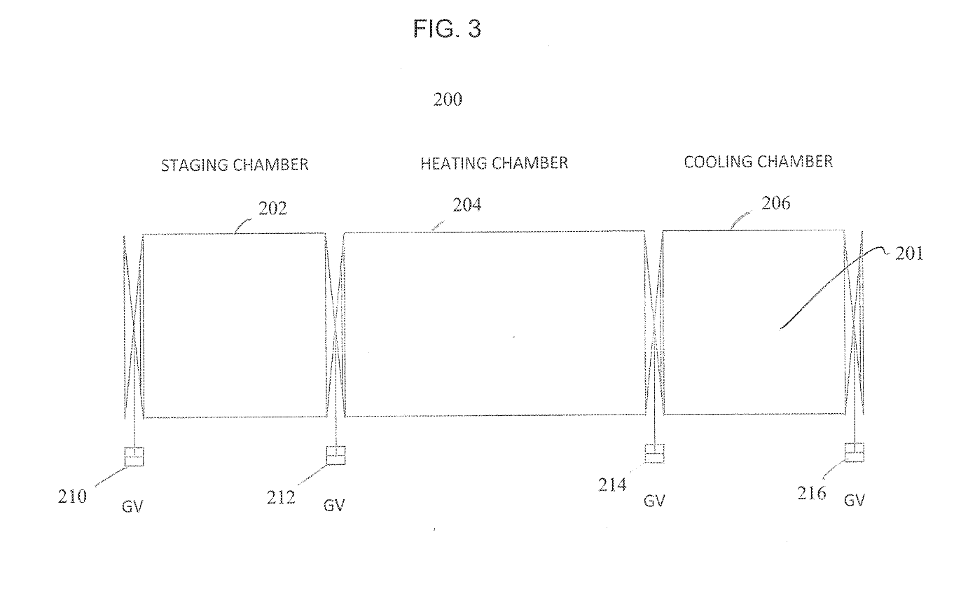

Main Function of Each Component in the Multi-Chamber Heating Furnace as illustrated in FIG. 3, furnace assembly 200 may be situated in a facility (not shown) so the substrate to be processed is moved horizontally in the direction of the arrow 201 from furnace chamber 202, chamber 204 and chamber 206 using gate valve 210, gate valve 212, and gate valve 214, that each function in the manner discussed above with reference to FIG. 2. As described previously, every chamber is essentially of similar design.

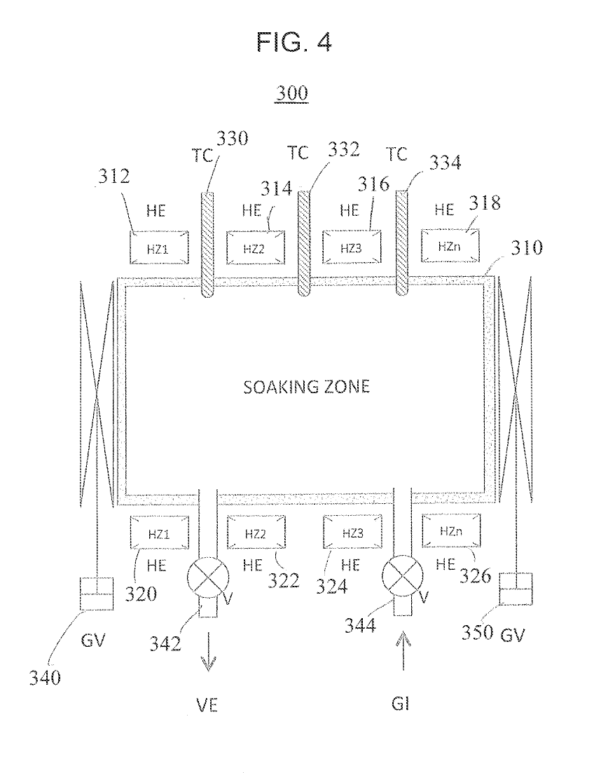

FIG. 4 shows a schematic representation of one of the heating chambers, chamber 310. A wide soaking zone is created inside the heating chamber, to maximize processing yield, as shown in FIG. 4. The wider the soaking zone, the bigger the amount of substrate (or wafers) bed that can be processed in one heating batch. To achieve a uniform and wide soaking zone, the heating elements (HE in FIG. 4) are synchronized vertically (top and bottom, as shown by HZ1, HZ2, HZ3, HZn in FIG. 4), dividing the heating chamber in individual heating zones. HZn refers to the fact that a number of additional heating elements are distributed in additional heating zones of the heating chamber depending on its specific size. Each heating zone's temperature is independently controlled, by means of controlling the output of each heating element pair individually. As stated above, thermocouples are strategically placed inside each of the heating zones in order to monitor each individual zone temperature, and provide this feedback to the temperature controlling mechanism (or heating elements).

Further as stated above, most of the properties and design of the three chambers may be almost identical, with the exception of some of the dimensions. However, in order to achieve the desired soaking zone in the main heating chamber, this particular chamber width is preferably designed to be slightly wider (or longer) compared to the other two heating chambers, so the desired soaking zone may be achieved.

The main preferred specifications of the heating chambers are as follows: heating temperature up to 1700° K and an attainable vacuum exhaust up to 0.01 Pa.

### Material Flow in A Typical Operation Mode

In a standard in-line operation mode, the wafers, substrate, or material being processed flow in the multi-chamber heating apparatus may be as follows:

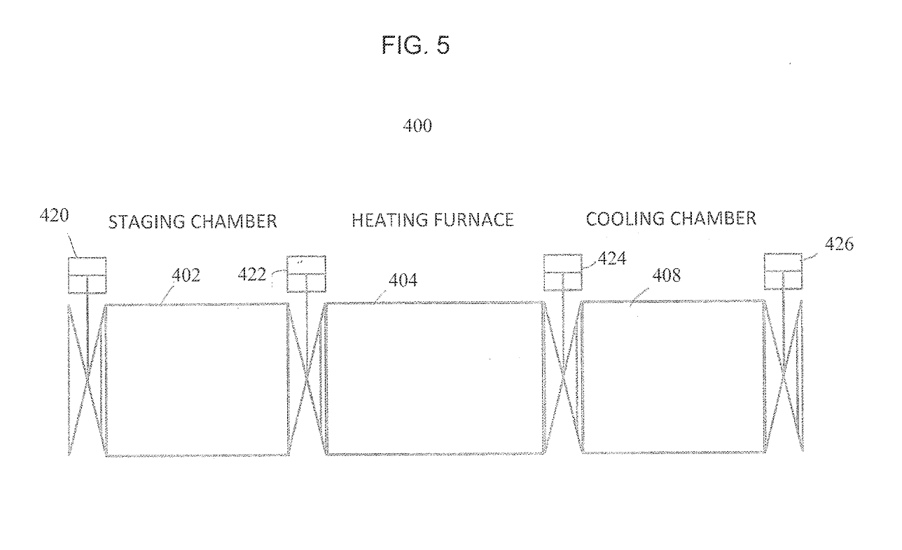

(1) Standby mode step 1 (illustrated in FIG. 5)

Target processing temperature for the main chamber 404 and staging chamber 402 is set and achieved. Post-processing chamber 408 is also set at the same pressure as main heating chamber 404.

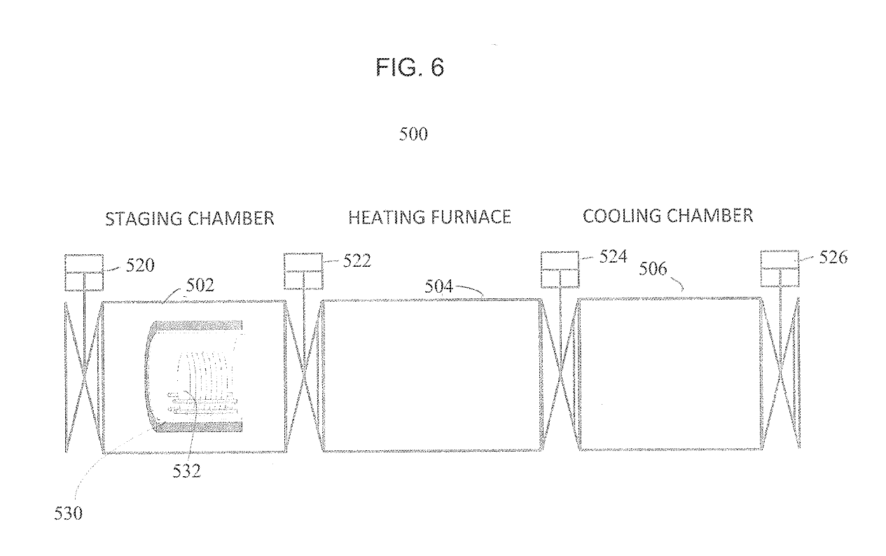

(2) Substrate boat loading step 2 (illustrated in FIG. 6)

Substrate boat 530 containing wafers 532 is loaded into staging chamber 502. Then, the target internal pressure is reached and the target processing gas is introduced to replace all the gases in the chamber.

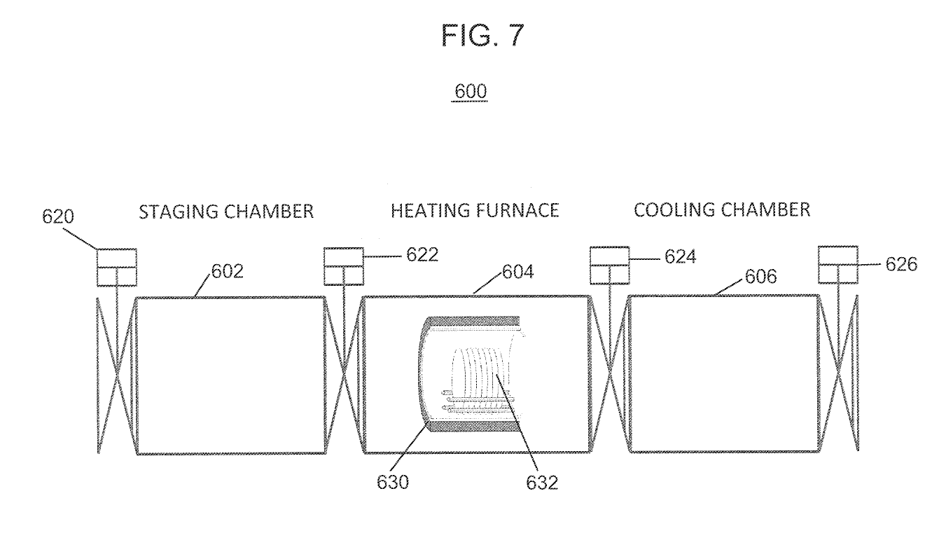

(3) Main heating process step 3 (illustrated in FIG. 7)

Once the substrate boat 630 is pre-heated, gate valve mechanism (GV2) 622 is opened, and the substrate boat 630 is loaded into the main heating chamber 604. Here the wafers 632 our processed at the target time, temperature, and atmosphere. While this occurs, the next substrate boat may be loaded into the staging chamber 602.

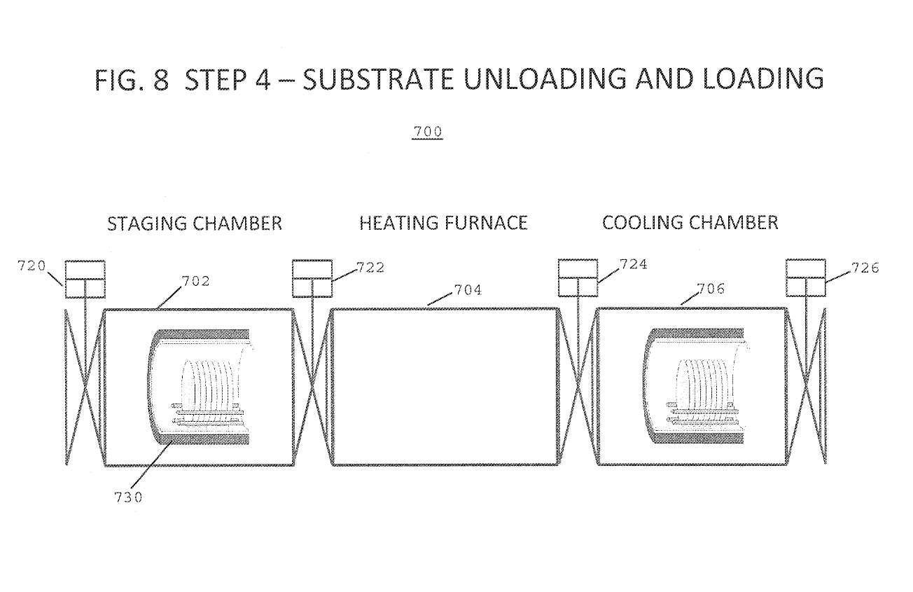

(4) Substrate unloading step 4 (illustrated in FIG. 8)

After substrate boat 730 is processed in main heating chamber 704, the substrate boat is unloaded from chamber 704 into the post-processing chamber 706, opening the gate valve mechanism (GV3) 724. Here the substrate may be post processed, whether it is cooled down rapidly, or whether an additional post processing is performed under controlled temperature, processing gas and pressure.

(5) Loop back to be standby mode step 1.

The foregoing description of a typical operational mode of the apparatus of the present invention includes a separate set of numbers for each of the staging, heating and cooling chambers and associated valves and other elements in each of the figures and does not necessarily mean that a different staging, heating and cooling chambers are used.

The foregoing description of preferred embodiments of the present invention has been provided for the purposes of illustration and description. It is not intended to be exhaustive or to limit the invention to the precise forms disclosed. Various additions, deletions and modifications are contemplated as being within its scope. The scope of the invention is, therefore, indicated by the appended claims rather than the foregoing description. Further, all changes which may fall within the meaning and range of equivalency of the claims and elements and features thereof are to be embraced within their scope.

We claim:

1. A multi-chamber thermo photovoltaic furnace, comprising:
a first chamber, for preheating a plurality of substrates positioned within at least one substrate boat to a desired condition, having an inlet gate and an outlet gate;
an inlet gate valve operably connected to the inlet gate of said first chamber for loading the chamber with the substrate boat;
a second chamber, for heating the substrates to a desired temperature under controlled process conditions, having an inlet gate and an outlet gate;
an intermediate gate valve operably connected between the outlet gate of said first chamber and the inlet gate of said second chamber for allowing the substrate boat to move from said first chamber into said second chamber;
a third chamber for cooling down the substrates having an inlet gate and an outlet gate; and
an outlet gate valve operably connected to the outlet gate of said third chamber for unloading the substrate boat while maintaining the controlled process conditions within said first and second chambers.

2. The furnace of claim 1 wherein said inlet gate valve is capable of continuously processing the substrates.

3. The furnace of claim 1 wherein said substrate boat is capable of holding at least 200 substrates.

4. The furnace of claim 1 wherein each of said first, second and third chambers are each equipped with one or more independent heating elements.

5. The furnace of claim 4 wherein the heating elements are capable of maintain temperatures within a range from room temperature to 1700° K (about 1426° C.).

6. The furnace of claim 1 8 wherein said first second and third chambers are equipped with a vacuum exhaust to maintain a vacuum of down to 0.01 Pa.

7. The furnace of claim 6 wherein each of said first, second and third chambers are equipped with one or more thermocouples.

8. The furnace of claim 1 wherein a timer operably connected to the furnace for synchronizing movement of the substrate from the substrate boat as it unloads from said third chamber with the movement of the substrate boat from said first chamber into aid second chamber.

9. The furnace of claim 6 wherein at least said second chamber is equipment with a gas valve for the supplying process gas.

10. A method for processing photovoltaic devices, comprising:
Loading a first chamber having an inlet gate and an outlet gate with a plurality of substrates positioned on a substrate boat,
preheating the plurality of substrates to a desired condition in the first chamber,
loading a second chamber with the plurality of substrates positioned on the substrate boat,
heating the substrates to a desired temperature under controlled process conditions in the second chamber,
loading a third chamber with the plurality of substrates positioned on the substrate boat, and
cooling down the substrates in the third chamber.
